(19) United States
(12) Patent Application Publication
(10) Pub. No.: US 2017/0160338 A1
(43) Pub. Date: Jun. 8, 2017

(54) INTEGRATED CIRCUIT RELIABILITY ASSESSMENT APPARATUS AND METHOD

(71) Applicant: Intel Corporation, Santa Clara, CA (US)

(72) Inventors: Christopher F. Connor, Hillsboro, OR (US); Bruce Querbach, Beaverton, OR (US); Gordon McFadden, Hillsboro, OR (US); Hanmant P. Belgal, El Dorado Hills, CA (US); Rahul Khanna, Portland, OR (US)

(21) Appl. No.: 14/961,824

(22) Filed: Dec. 7, 2015

(51) Int. Cl. G01R 31/28; G11C 29/00; G11C 7/00

(52) U.S. Cl. CPC G01R 31/2834; G11C 7/00; G11C 29/00; G01R 31/2894

(57) ABSTRACT

In embodiments, apparatuses, methods and storage media (transitory and non-transitory) are described that include a reliability physics module stored in non-volatile memory and compute logic to calculate at least one of an estimated amount of lifetime consumed or an estimated amount of lifetime remaining after a period of operation of an integrated circuit. In embodiments, the calculation may be based at least in part on the reliability physics model and data of at least one physical condition of the integrated circuit sensed during or at the end of the period of operation. Other embodiments may be described and/or claimed.

### TECHNICAL FIELD

The present disclosure relates to the field of integrated circuit devices, in particular, to reliability assessment of integrated circuit devices.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Reliability physics modeling is used to estimate integrated circuit (IC) projected lifetime under specified operating conditions. Currently, IC chip lifetimes are typically estimated at the time of manufacture and assigned based on operating conditions that may not be exceeded for the estimate to remain valid. This does not take into account actual operating conditions during use of the IC chip and does not allow an end user to understand the effect changed operating conditions may have on projected IC chip lifetime. With no method to assess reliability in real time with respect to actual product use and environmental conditions, extra reliability that may be in the form of additional product lifetime and/or performance may be unused, translating to additional product cost over time.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the Figures of the accompanying drawings.

FIG. 1 is a block diagram of a reliability assessment engine having IC reliability assessment technology of the present disclosure, in accordance with various embodiments.

FIG. 2 is a block diagram of a memory module incorporating a reliability assessment engine, in accordance with various embodiments.

FIG. 3 is a block diagram of a system on a chip incorporating a reliability assessment engine, in accordance with various embodiments.

FIG. 4 is a block diagram of a solid state drive incorporating a reliability assessment engine, in accordance with various embodiments.

FIG. 5 is a diagram of a memory block such as may be included in the solid state drive incorporating a reliability assessment engine, in accordance with various embodiments.

FIG. 6 depicts a raw bit error rate as a function of program/erase cycles and read disturb count as may be implemented in a reliability physics model, in accordance with various embodiments.

FIG. 7 is a block diagram of a datacenter environment including reliability assessment technology, in accordance with various embodiments.

FIG. 8 is a flow diagram of an example process of assessing reliability of an integrated circuit that may be implemented on a reliability assessment engine described herein, in accordance with various embodiments.

FIG. 9 illustrates an example computing environment suitable for practicing various aspects of the disclosure, in accordance with various embodiments.

FIG. 10 illustrates an example storage medium with instructions configured to enable an apparatus to practice various aspects of the present disclosure, in accordance with various embodiments.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “logic” and “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality. The term “module” may refer to software, firmware and/or circuitry that is/are configured to perform or cause the performance of one or more operations consistent with the present disclosure. Software may be embodied as a software package, code, instructions, instruction sets and/or data recorded on non-transitory computer readable storage mediums. Firmware may be embodied as code, instructions or instruction sets and/or data that are hard-coded (e.g., nonvolatile) in memory devices. “Circuitry”, as used in any embodiment herein, may comprise, for example, singly or in any combination, hardwired circuitry, programmable circuitry such as computer processors comprising one or more individual instruction processing cores, state machine circuitry, software and/or firmware that stores instructions executed by programmable circuitry. The modules may collectively or individually be embodied as circuitry that forms a part of a computing device. As used herein, the term “processor” may be a processor core.

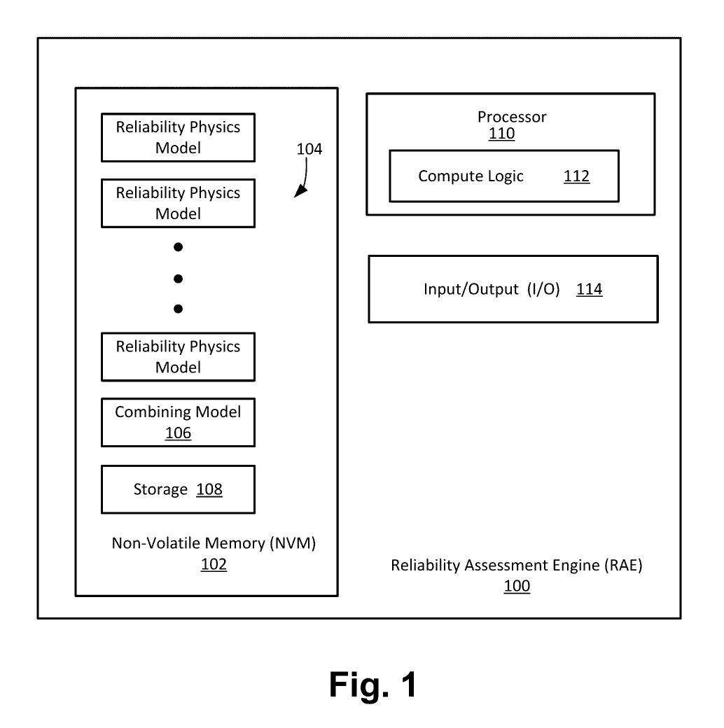

Referring now to FIG. 1, a reliability assessment engine (RAE) 100 to integrally assess reliability of an integrated circuit, in accordance with various embodiments, is illustrated. In some embodiments, the RAE 100 may include processor 110, non-volatile memory (NVM) 102 and input/output (I/O) 114, coupled with each other. NVM 102 may be configured to store one or more reliability physics models 104 used for the reliability assessment. In various embodiments, the reliability physics models 104 may include one or more of a time dependent dielectric breakdown model, a bias temperature stability model, an electromigration model, a negative and positive (negative/positive) bias temperature instability model, an integrated reliability model, a package die crack model, an intrinsic charge loss model, a stress induced leakage current model, a read/write disturb model, or other reliability physics models. In various embodiments, models including one or more formulas having one or more variable parameters representing physical IC operating conditions may be stored in the NVM 102 at a time of IC manufacture. In some embodiments, the models may be updated in a firmware and/or software update process such that one or more revised models may be stored in place of or in addition to the models stored at the time of manufacture.

In some embodiments, the time dependent dielectric breakdown model may model transistor dielectric lifetime, the bias temperature instability model may model interconnect lifetime with respect to shorting mechanisms, the electromigration model may model interconnect lifetime with respect to open circuits, the negative/positive bias temperature instability model may model a transistor failure mechanism for P and N type metal oxide semiconductor (MOS) devices, the integrated reliability model may model defect/infant mortality, the package die crack model may model electrical edge damage monitor measurements, the intrinsic charge loss model may model a detrapping thermal data retention mechanism, the stress induced leakage current model may model a voltage data retention mechanism, and the read/write disturb model may model threshold voltage shifts in a memory cell caused by a read operation in another, relatively near, memory cell. In various embodiments, the read/write disturb model may be applicable to memory ICs, the intrinsic charge loss model may be applicable to flash memory ICs, and the time dependent dielectric breakdown, bias temperature instability, electromigration, negative/positive bias temperature instability (NBTI/PBTI), integrated reliability, package die crack, and stress induced leakage current models may be applicable to various types of ICs including logic and memory ICs. However, any model can be used to model performance of any device.

In some embodiments, a reliability physics model may use one or more equations to calculate an expected failure rate of an IC. In various embodiments, a defect reliability/infant mortality model, shown as equation (1), may be used in combination with a fail rate equation, shown as equation (2), to calculate an expected failure rate of an IC device.

$${t}_{eff} = {\sum }_{i = states} {t}_{readout} {TIS}_{i} {DC}_{i} exp [ C ( {V}_{i} - {V}_{ref} ) - \frac{{E}_{a}}{{k}_{b}} ( \frac{1}{{T}_{{use}_{i}}} - \frac{1}{{T}_{ref}} ) ] \qquad ( 1 )$$

With respect to equation (1): TISᵢ is the percent of time the unit spends in state i according to the use model; DCᵢ is the duty cycle parameter for state i (which may differ from block to block); Vᵢ and Tᵢ are the voltage and temperature for a particular block; t_{readout} is incremental time; and k_{b} is the Boltzmann constant.

As shown in equation (2), in various embodiments, two effective stress times may be used to compute fail rate: the effective stress time due to burn-in stress alone, t_{eff}^{BI}, and the total effective stress time in burn-in plus use stress, t_{eff}. To determine the expected failure rate, equation (2) may be used, where Φ is the cumulative normal distribution function, t_{eff} is the effective stress time including use and burn-in, t_{eff}^{BI} is the effective stress time in burn-in, μ is the mean of the natural logarithm of the lifetime distribution, PURDD is per unit defect density, A is the area under consideration, and σ is the standard deviation.

$$〈 S 〉 = \frac{{S}_{cum}}{{S}_{BI}} = {[ \frac{1 - Φ ( \frac{ln ( {t}_{eff} ) - μ}{σ} )}{1 - Φ ( \frac{ln ( {t}_{eff}^{BI} ) - μ}{σ} )} ]}^{\frac{A PURDD}{{A}_{ref} {D}_{ref}}} \qquad ( 2 )$$

Table 1 provides additional information with respect to the parameters of equations (1) and (2), according to various embodiments.

TABLE 1

| Parameter | Description | Units |
|---|---|---|
| μ | Lognormal mean of the infant mortality lifetime | Ln(hrs) |
| | (in hrs) for the reference area at the reference | |
| | defect density. | |
| σ | Lognormal standard deviation of the infant mortality | |
| | lifetime distribution for the reference area at the | |
| | reference defect density. | |
| A_{ref} | Reference die area. | cm² |
| D_{ref} | Reference electric field for voltage acceleration | defects/ |
| | | cm² |
| T_{ref} | Reference temperature for thermal acceleration | C. |
| V_{ref} | Reference voltage for voltage acceleration | V |
| C | Voltage acceleration factor. | 1/V |
| Eₐ | Thermal activation energy | eV |

In various embodiments, a combining model 106 used in the reliability assessment may also be stored in the non-volatile memory 102, which may be a statistical model such as a Markov failure prediction model or another type of model to combine more than one of the reliability physics models 104. The RAE 100 may also include storage 108 that may be within the non-volatile memory 102. In various embodiments, the storage 108 may be used to store data used for inputs to the reliability physics models 104, intermediate or final outputs of the RAE 100, and/or other data used or generated by the RAE 100 for the reliability assessment. In some embodiments, the processor 110 may include compute logic 112. In various embodiments, the input/output module 114 may be used to receive and/or send data to and/or from other parts of an IC and/or other devices that may not be on the IC.

In some embodiments where the combining model 106 may be a Markov failure prediction model, a failure state of the IC may be estimated by combining Markov chains from multiple components. In some embodiments, a chip with the IC may be modeled as being in a normal, repair, or fail state at a particular point in time. An estimated degradation of the chip may be estimated with a Markov chain that estimates system failure based on combined reliability physics models. In some embodiments, when the system undergoes a change of state at regular time intervals, it may be described by a stochastic process in which the distribution of future states depends on the present state. In various embodiments, the failure rate may be modeled by regressing physics-based reliability measurements that act as fundamental components driving the Markov process. In some embodiments, a statistical model such as a Markov failure prediction model may also be used to model an estimated failure of a device with multiple IC chips, each chip having an integrated RAE, based at least in part on results from the reliability physics models from the RAEs in the chips of the device.

In various embodiments, the reliability physics models 104 and the combining model 106 may be stored in the non-volatile memory 102 at the time of production of a device that includes the RAE 100, along with an expected maximum IC lifetime parameter. In some embodiments, the reliability physics models 104 may include formulas and/or algorithms that may use one or more inputs that may include one or more sensed voltages, an average of the one or more sensed voltages, one or more sensed temperatures, an average of the one or more sensed temperatures, one or more workload measures, an average of the one or more workload measures, and/or other physical conditions of an IC sensed during a period of operation of the IC. In some embodiments, the sensed voltages, sensed temperatures, and/or workload measures of the IC may be received from a power control unit (PCU) of the IC. In various embodiments alternative and/or additional inputs such as area and/or use conditions may be used. In some embodiments, a workload measure may be a representation of aggregate use of a particular IC sub-block.

In various embodiments, the RAE 100 may continually calculate a lifetime of the IC that has been consumed under each reliability physics model 104. The inputs to the calculation may be periodically stored in the non-volatile memory 102. The RAE 100 may calculate an amount of lifetime consumed and/or an amount of lifetime remaining for an IC using the inputs, one or more reliability physics models 104, and/or the combined model 106. In some embodiments, the compute logic 112 may perform the calculation. In other embodiments, an external processor, such as a CPU, coupled with the RAE 100 may perform the calculation instead. In various embodiments, the amount of lifetime consumed, the amount of lifetime remaining, and/or another result generated by the RAE 100 may be stored in the non-volatile memory 102 in a secure fashion, such as by using an encrypted key. The securely stored results may be accessible from outside the RAE 100 through the I/O module 114 in various embodiments. In some embodiments, the RAE 100 may calculate more than one estimated amount of lifetime remaining based at least in part on the use of different proposed operating parameters such as more than one proposed operating temperature, more than one proposed operating voltage, and/or more than one proposed workload. In embodiments, a computer may display options to a user so that the user may be able to select among the multiple different proposed operating parameters such that tradeoffs can be made that allow the amount of operating lifetime to be reduced in order to gain additional performance or to be increased when some level of performance is reduced.

In some embodiments, the processor 110 may assess workload of the IC which is periodically stored into NVM 102 along with the voltage and/or temperature experienced by the IC while performing the workload. Based on a predefined maximum effective stress at a given time, the processor 110 or a CPU coupled with the RAE 100 may output controls for regulation of the voltage, temperature, and/or workload of the IC based on the actual effective stress, while ensuring that a device having the RAE 100 does not exceed the maximum possible stress at a given point in time. In various embodiments, a power control unit (PCU) of the IC may write workload, voltage, and temperature for each sub-component of an IC into the NVM 102. Reliability metrics may be calculated and aggregated at a less frequent rate than parameters are stored in some embodiments. The RAE 100 may provide updates to an operating system (OS), reliability, availability, and serviceability (RAS), and/or manageability engine (ME) components of the IC, on cumulative reliability lifetime in a variety of metrics. In embodiments, real-time consumption metrics may be extracted and viewed by an administrator of a system having the integrally assessed IC. In some embodiments, the RAE 100 itself, or the IC may have onboard memory for warranty verification with respect to voltage, temperature, and workload of the IC or some or all possible sub-blocks of the IC made available. A user may then utilize the IC for a longer lifetime than originally intended if user conditions were less harsh, or a user may utilize the IC under harsh conditions that extract performance above specified operating parameters. In various embodiments, this may allow extra-long life parts, such as beyond a lifetime of seven years with limited usage, or extra performance parts, such as a performance improvement from two to ten times at the expense of a shorter part lifetime.

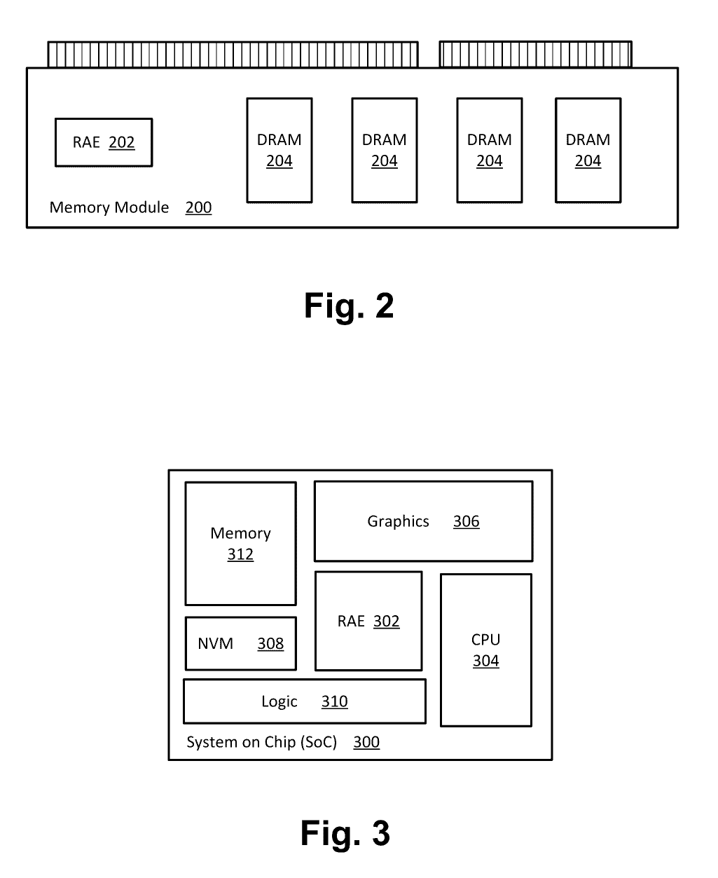

Referring now to FIG. 2, a block diagram of a memory module 200 is shown, incorporating a RAE 202 that may be structured in similar fashion to RAE 100, in accordance with various embodiments. In some embodiments, the memory module 200 may be a dual in-line memory module (DIMM) including a plurality of dynamic random access memory (DRAM) components 204. Other types of memory modules may be used in other embodiments. The RAE 202 may include non-volatile random access memory (NVRAM) corresponding to the NVM 102 to store reliability physics models and combining models relating to the DRAM components 204. In embodiments, the RAE 202 may include a processor with compute logic as earlier described with reference to FIG. 1 to calculate an estimated amount of lifetime consumed and/or an estimated amount of lifetime remaining for the memory module 200 and/or individual DRAM components 204. In other embodiments, the calculations may be performed by a memory controller or central processing unit (CPU) of a computer with which the memory module 200 may be coupled rather than by a processor in the RAE 202.

Examples of nonvolatile memory include three dimensional crosspoint memory device, or other byte addressable nonvolatile memory devices, multi-threshold level NAND flash memory, NOR flash memory, single or multi-level Phase Change Memory (PCM), Resistive RAM (ReRAM/RRAM), phase-change RAM exploiting certain unique behaviors of chalcogenide glass, nanowire memory, ferroelectric transistor random access memory (FeTRAM), Ferroelectric RAM (FeRAM/FRAM), Magnetoresistive Random-Access Memory (MRAM), Phase-change memory (PCM/PCMe/PRAM/PCRAM, aka Chalcogenide RAM/CRAM) conductive-bridging RAM (cbRAM, aka programmable metallization cell (PMC) memory), SONOS (“Silicon-Oxide-Nitride-Oxide-Silicon”) memory, FJRAM (Floating Junction Gate Random Access Memory), Conductive metal-oxide (CMOx) memory, battery backed-up DRAM spin transfer torque (STT)-MRAM, magnetic computer storage devices (e.g. hard disk drives, floppy disks, and magnetic tape), or a combination of any of the above, or other memory, and so forth. In one embodiment, the nonvolatile memory can be a block addressable memory device, such as NAND or NOR technologies. Embodiments are not limited to these examples.

Referring now to FIG. 3, a block diagram of a system on a chip (SoC) 300 is shown, incorporating a RAE 302 that may be structured in similar fashion to RAE 100, in accordance with various embodiments. In some embodiments, the SoC 300 may be an IC that includes a plurality of blocks such as the RAE 302, a CPU 304, a graphics processor 306, non-volatile memory 308, a logic block 310, and a memory block 312. Additional and/or alternative types of blocks may be included in the SoC 300 in other embodiments. In various embodiments, each block may have an actual voltage, temperature, and workload per given time that may be measured and provided to the RAE 302 as data representing the voltage, temperature, and workload of the block and/or average of the voltage, temperature and/or workload of the block over a predetermined time period. In some embodiments, the RAE 302 may be capable of receiving instructions from outside the RAE 302 on how to operate, such as from a reliability rack scale architecture chip (RRSAC) using an encrypted key.

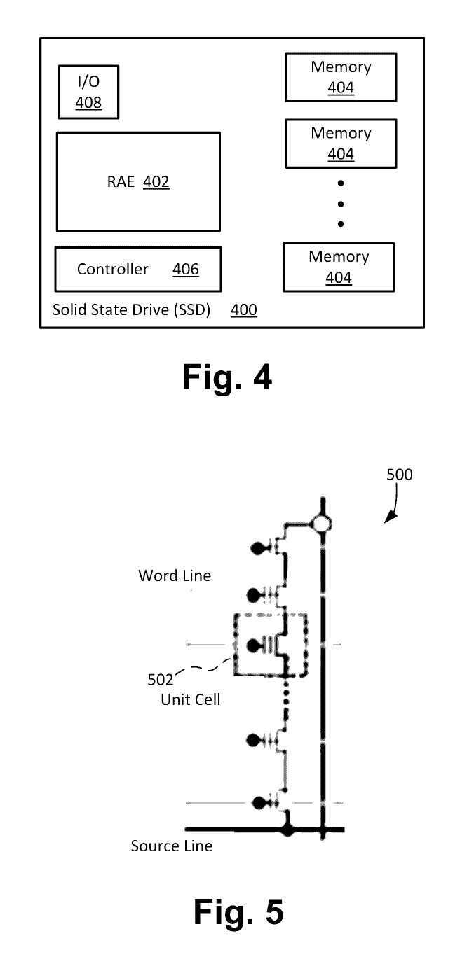

Referring now to FIG. 4, a block diagram of a solid state drive (SSD) 400 is shown, incorporating a RAE 402 that may be structured in similar fashion to RAE 100, in accordance with various embodiments. In some embodiments, the SSD 400 may include a plurality of memory modules 404 that may be flash memory modules. The SSD 400 may include a SSD controller 406 and an I/O interface 408 in various embodiments. The RAE 402 may be to monitor and assess reliability of one or more of the memory modules 404 in various embodiments. In some embodiments, the RAE 402 may allow for memory cell level performance assessment and tracking via physics-based mechanisms which may augment first order tracking and correcting of cell failures and self-monitoring, analysis, and reporting technology (S.M.A.R.T.) wearout indicator attribute E9 to a more accurate, assessed value.

Referring now to FIG. 5, a diagram of a memory block 500 such as may be included in one of the memory modules 404 in various embodiments is shown. The memory block 500 may include a unit cell 502 for which physical conditions such as program/erase cycles, threshold program voltage shifts, and/or other conditions may be sensed or determined. Reliability physics models that may be included in a RAE such as the RAE 402 of FIG. 4 may use one or more of the sensed conditions such as program/erase cycles, threshold program voltage shifts, or other conditions as inputs. The RAE 402 may calculate a parameter such as a raw bit error rate (RBER) using one or more of the reliability physics models. In some embodiments, the RAE 402 and/or the controller 406 may dynamically adjust a read-disturb handling rate of the SSD 400 based at least in part on the calculated RBER.

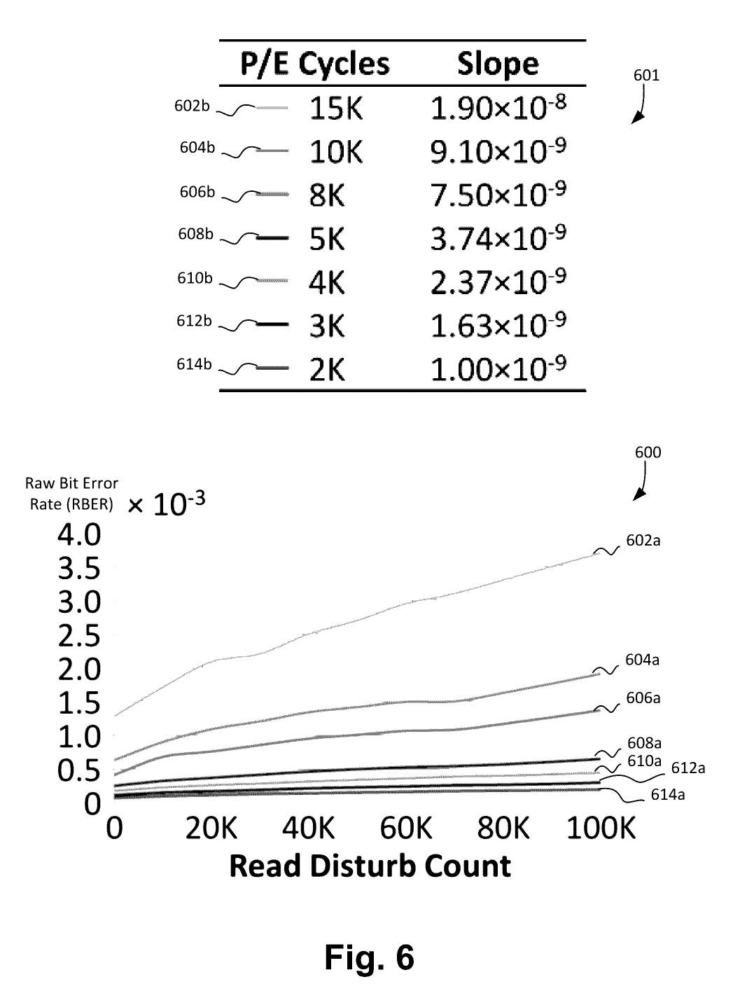

Referring now to FIG. 6, a graph 600 depicts a RBER as a function of program/erase (P/E) cycles and read disturb count for memory that may include a block such as the block 500 of FIG. 5 and that may be a part of a device such as the SSD 400 of FIG. 4. A legend 601 relates varying P/E cycles to the graph 600 and includes a slope value for each P/E cycle value fitted to the graph 600. The graph 600 shows a first RBER 602a graphed as a function of read disturb count for a first P/E cycle count 602b. A second RBER 604a is graphed as a function of read disturb count for a second P/E cycle count 604b. The graph continues for third though seventh RBER 606a, 608a, 610a, 612a, and 614a graphed as a function of read disturb count for third through seventh P/E cycle count 606b, 608b, 610b, 612b, and 614b, respectively. In various embodiments a RAE, such as the RAE 402, may be loaded with one or more RBER models based at least in part on the graph 600 that may relate to one or more memory cell blocks which may relate to a whole die or a subset of a die, where the RBER model may be modeled at least in part on a power law with coefficients that may depend on process technology, the particular memory product, manufacturing measurements, and/or other conditions. In some embodiments, an SSD such as the SSD 400, or a device that includes one or more memory devices, may monitor estimated RBER as calculated using the model as functions of NAND cycles and may continuously update a RAE such as the RAE 402, while dynamically adjusting a read-disturb handling rate based on the estimated RBER.

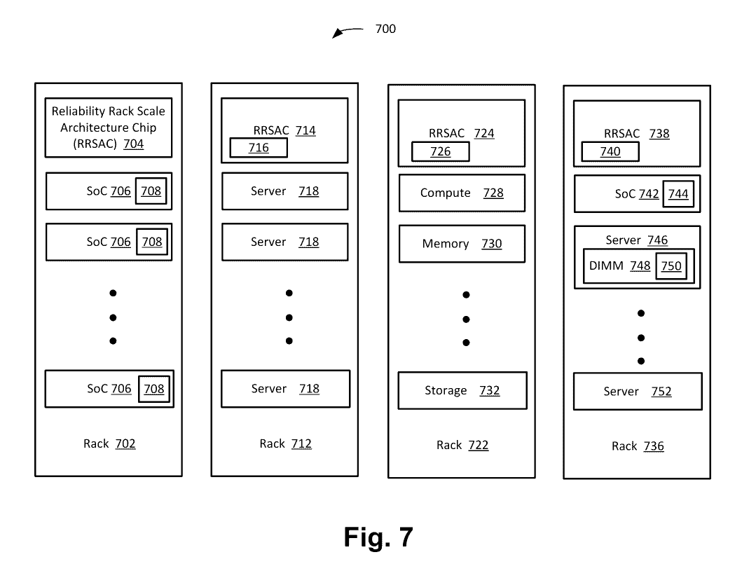

Referring now to FIG. 7, a datacenter environment 700, including reliability assessment technology of the present disclosure, in accordance with various embodiments, is illustrated. A first rack 702 may have a plurality of components that may include a reliability rack scale architecture chip (RRSAC) 704 coupled with a plurality of SoCs 706, each of which may include a RAE 708 and may be configured in a similar fashion to the SoC 300 described with respect to FIG. 3 in various embodiments. In some embodiments, the RRSAC 704 may be communicatively coupled with the RAEs 708 such that the RRSAC 704 may receive estimated amounts of lifetime remaining for the SoCs 706 and/or individual blocks of the SoCs 706. In some embodiments, the RRSAC 704 may be configured to issue commands and/or instructions to the RAEs 708 to direct them to operate components on the SoCs 706 with specified operating parameters.

A second rack 712 may have a plurality of components that may include a RRSAC 714 that may include a RAE 716. The second rack 712 may include a plurality of servers 718 coupled with the RRSAC 714. The servers 718 may each include one or more ICs that may not have an integrated RAE in some embodiments. The identities of ICs on the servers 718 may be provided to the RAE 716 using a self-identification process, or they may self-identify to a CPU on their respective server, with each server 718 providing the identities of the ICs to the RAE 716. In various embodiments, a power control unit such as on a CPU of each server 718 may provide various sensed physical conditions of the ICs on the servers to the RAE 716. The RAE 716 may perform calculations similar to those performed by the RAE 100 of FIG. 1, but for multiple ICs that may reside in multiple servers 718. In various embodiments, the RRSAC 714 may be configured to issue commands and/or instructions to the servers 718 such that they operate ICs monitored by the RAE 716 with parameters determined by the RRSAC 714 or a user with access to the RRSAC 714.

A third rack 722 may have a plurality of components that may include a RRSAC 724 that may include a RAE 726. The components in the third rack 722 may include disaggregated components such as a computing module 728 that may include a plurality of processors, a memory module 730, and a storage module 732 that may be coupled with each other using a networking method such as silicon photonics networking technology in some embodiments or other networking technology. In various embodiments, the computing module 728, the memory module 730, and the storage module 732 may each include a plurality of ICs. In some embodiments, some or all of the ICs may include an RAE. In other embodiments, the ICs may not include an RAE. In various embodiments, the RAE 726 may be configured to assess the reliability of ICs in the third rack 722 that do not include an RAE. In various embodiments, the RRSAC 724 may be configured to monitor and/or provide commands or instructions to the ICs having an integral RAE as well as the ICs without an integral RAE.

A fourth rack 736 may have a plurality of components that may include a RRSAC 738 that may include a RAE 740. The components in the fourth rack 736 may include a mixture of components with ICs having an integrated RAE and components with ICs that do not include an RAE. In some embodiments, the components with ICs having an integrated RAE may include components such as a SoC 742 with an RAE 744 and a server 746 having a DIMM 748 with an integrated RAE 750. In some embodiments, the components without an RAE may include a server 752 that does not include ICs having an integrated RAE. In various embodiments, the RRSAC 738 may monitor and control the ICs in the fourth rack 736 in similar fashion to that described with respect to RRSAC 704, RRSAC 714, and/or RRSAC 724.

In some embodiments, some or all IC chips in one or more racks may include a reliability assessment engine within its power control unit governing applied voltage with respect to physics based reliability mechanisms. A reliability rack scale architecture device that may include an RRSAC may optimize conditions for devices having IC chips with RAEs, maximizing performance across load and predicting which devices may require replacement at various points in time. This optimization may be conducted across all types of ICs used in the rack scale architecture in various embodiments. In some embodiments, the reliability rack scale architecture may use memory to store aggregate characteristics regarding workloads, voltage, and temperature for every discretized portion of a given component, allowing for autonomous analytics and warranty verification in addition to cumulative reliability lifetime calculation. This may be complementary to and may augment reliability, availability, and serviceability (RAS), manageability engine (ME), and/or SSD SMART features in various embodiments. In some embodiments, commands may be issued via encrypted keys stored within memory of the RRSAC to optimize the performance workload of the rack. In embodiments, an RRSAC may include algorithms to alert an RAS module when devices are nearing the end of their effective lifetime. The RRSAC may store reliability information cross-linked with types of workload in order to give an operator feedback on performance or lifetime optimization methods available. In embodiments, a device having an RAE within a rack may self-assess performance capabilities and scale an applied voltage to obtain extra clock frequencies for workloads as needed. An RRSAC may monitor performance of devices in a rack and alter device performance where devices indicate performance advantages are possible, enabling a greater overall performance for the server rack.

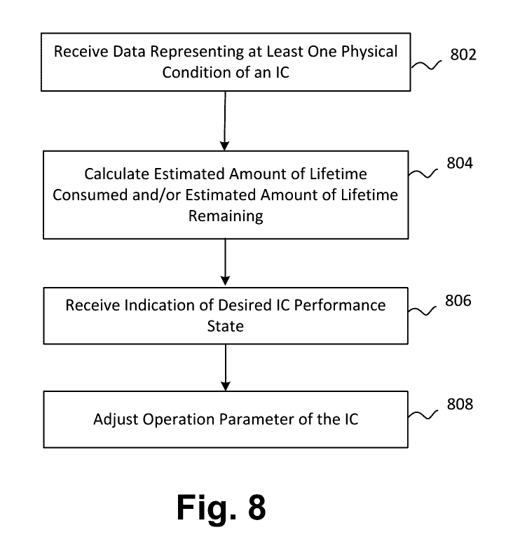

FIG. 8 is a flow diagram of an example process 800 of assessing reliability of an IC that may be implemented on a RAE described herein, in accordance with various embodiments. In various embodiments, some or all of the process 800 may be performed by RAE 100, RAE 202, RAE 302 RAE 402, RAE 708, RAE 716, RAE 726, RAE 740, RAE 744, RAE 750, CPU 304, RRSAC 704, RRSAC 714, RRSAC 724, RRSAC 738 or the controller 406 of the SSD 400 described with respect to FIGS. 1-5 and FIG. 7. In other embodiments, the process 800 may be performed with more or less modules and/or with some operations in different order.

As shown, for embodiments, the process 800 may start at a block 802 where data representing at least one physical condition of an IC may be received. In various embodiments, the data may represent at least one physical condition of the IC sensed during or at the end of a period of operation of the IC. The sensed physical condition may include sensed voltage, an average of sensed voltage, sensed temperature, an average of sensed temperature, a workload measure, an average of a workload measure, and/or other conditions of the IC. At a block 804, an estimated amount of lifetime consumed and/or an estimated amount of lifetime remaining for the IC may be calculated based at least in part on a reliability physics model and the received data. In some embodiments, the calculation may be performed using two or more reliability physics models and a statistical model to combine the two or more reliability physics models. In various embodiments, the reliability physics models used in the calculation may include one or more of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model. In some embodiments, more than one estimated amount of IC lifetime remaining may be calculated based on differing proposed operating parameters.

At a block 806, an indication of a desired IC performance state may be received. The indication may be received from a user based on a selection between estimated amount of IC lifetime remaining based on differing operating parameter scenarios or may be received from a RRSAC, for example. At a block 808, an operation parameter of the IC may be adjusted based at least in part on the received indication. In various embodiments, the operating parameter adjusted may include one or more of a temperature, a voltage, or a workload of the IC, for example.

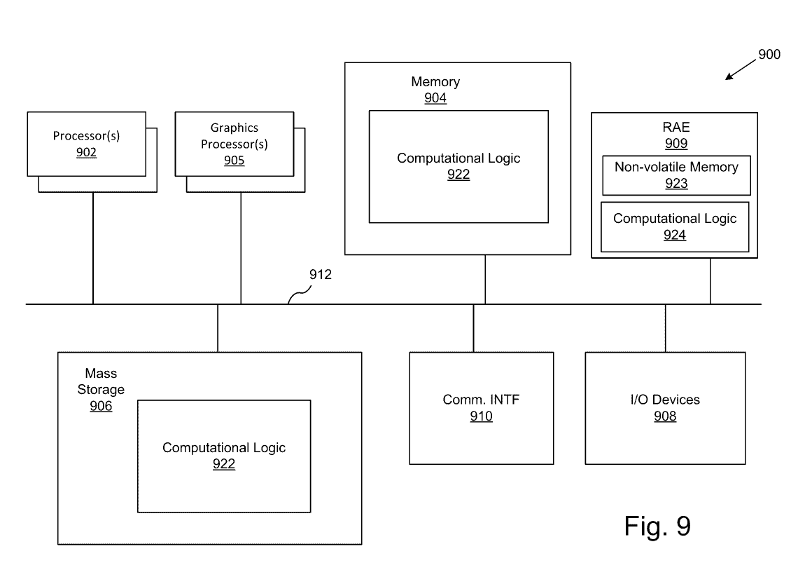

Referring now to FIG. 9, an example computer 900 suitable to practice the present disclosure as earlier described with reference to FIGS. 1-8 is illustrated in accordance with various embodiments. As shown, computer 900 may include one or more processors or processor cores 902, and system memory 904. In various embodiments, the one or more processors or processor cores 902 may include the CPU 304 of FIG. 3, processors in the SoCs 706 and 742 of FIG. 7, processors in the servers 718, 746, 752 of FIG. 7, processors in the compute module 728 of FIG. 7, or other processors or controllers described with respect to various embodiments. The system memory may include the memory module 200 in some embodiments. For the purpose of this application, including the claims, the term “processor” refers to a physical processor, and the terms “processor” and “processor cores” may be considered synonymous, unless the context clearly requires otherwise. Additionally, computer 900 may include one or more graphics processors 905, mass storage devices 906 (such as diskette, hard drive, SSD, compact disc read only memory (CD-ROM) and so forth), input/output devices 908 (such as display, keyboard, cursor control, remote control, gaming controller, image capture device, and so forth), RAE 909, and communication interfaces 910 (such as network interface cards, modems, infrared receivers, radio receivers (e.g., Bluetooth), and so forth). The mass storage devices 906 may include the SSD 400 of FIG. 4, in some embodiments. The elements may be coupled to each other via system bus 912, which may represent one or more buses. In the case of multiple buses, they may be bridged by one or more bus bridges (not shown). In embodiments, the RAE 909 may include non-volatile memory 923 and computational logic 924. In various embodiments, RAE 909 may be RAE 100, RAE 202, RAE 302, RAE 402, RAE 708, RAE 716, RAE 726, RAE 740, RAE 744, or RAE 750 of FIG. 1-5 or 7. In some embodiments, the RAE 909 may be included within an IC that includes memory 904, processor 902, mass storage 906, or graphics processor 905.

The communication interfaces 910 may include one or more communications chips that may enable wired and/or wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication interfaces 910 may implement any of a number of wireless standards or protocols, including but not limited to IEEE 702.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The communication interfaces 910 may include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, Ev-DO, and others. In various embodiments, the communication interfaces 910 may be configured to communicate using one or more wireless communication methods and topologies such as IEEE 802.11x (WiFi), Bluetooth, IEEE 802.15.4, wireless mesh networking, wireless personal/local/metropolitan area network technologies, or wireless cellular communication using a radio access network that may include a Global System for Mobile Communication (GSM), General Packet Radio Service (GPRS), Universal Mobile Telecommunications System (UMTS), High Speed Packet Access (HSPA), Evolved HSPA (E-HSPA), Long-Term Evolution (LTE) network, GSM Enhanced Data rates for GSM Evolution (EDGE) Radio Access Network (GERAN), Universal Terrestrial Radio Access Network (UTRAN), Evolved UTRAN (E-UTRAN), IEEE 802.22, IEEE 802.11af, IEEE 802.11ac, LoRa™, or SigFox.

Each of these elements may perform its conventional functions known in the art. In particular, system memory 904 and mass storage devices 906 may be employed to store a working copy and a permanent copy of the programming instructions implementing an operating system and one or more applications, collectively denoted as computational logic 922. Similarly, RAE 909 may include reliability physics models, a combining model, and/or storage in NVM 923 and/or programming instructions implementing the operations associated with the RAE 909, e.g., operations described for RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8, collectively denoted as computational logic 924. The system memory 904 and mass storage devices 906 may also be employed to store the data or local resources in various embodiments. The various programming instructions may be implemented by assembler instructions supported by processor(s) 902 or high-level languages, such as, for example, C, that can be compiled into such instructions.

The permanent copy of the programming instructions may be placed into mass storage devices 906 and/or RAE 909 in the factory, or in the field, through, for example, a distribution medium (not shown), such as a compact disc (CD), or through communication interface 910 (from a distribution server (not shown)). That is, one or more distribution media having an implementation of the agent program may be employed to distribute the agent and program various computing devices.

The number, capability and/or capacity of these elements 902-924 may vary, depending on whether computer 900 is a stationary computing device, such as a server, high performance computing node, set-top box or desktop computer, a mobile computing device such as a tablet computing device, laptop computer or smartphone, or an embedded computing device. Their constitutions are otherwise known, and accordingly will not be further described. In various embodiments, different elements or a subset of the elements shown in FIG. 9 may be used. For example, some devices may not include the graphics processor 905, may use a unified memory that serves as both memory and storage, or may include one or more RAE 909 within other components such as the processor 902, the memory 904, or the mass storage 906.

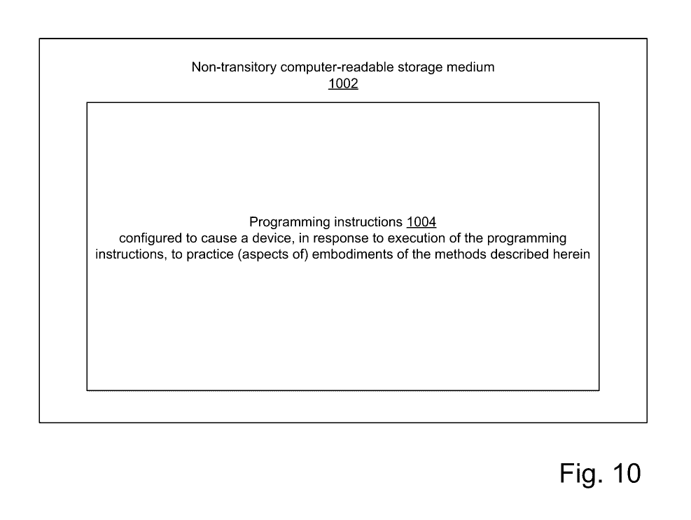

FIG. 10 illustrates an example at least one non-transitory computer-readable storage medium 1002 having instructions configured to practice all or selected ones of the operations associated with the RAE 100, RAE 202, RAE 302, RAE 402, RAE 708, RAE 716, RAE 726, RAE 740, RAE 744, RAE 750, or RAE 909 of FIGS. 1-5, 7, and 9, earlier described, in accordance with various embodiments. As illustrated, at least one computer-readable storage medium 1002 may include a number of programming instructions 1004. The storage medium 1002 may represent a broad range of persistent storage medium known in the art, including but not limited to flash memory, dynamic random access memory, static random access memory, an optical disk, a magnetic disk, etc. Programming instructions 1004 may be configured to enable a device, e.g., computer 900 (in particular, RAE 909) or RAE 100, RAE 202, RAE 302, RAE 402, RAE 708, RAE 716, RAE 726, RAE 740, RAE 744, or RAE 750 of FIG. 1-5 or 7, in response to execution of the programming instructions 1004, to perform, e.g., but not limited to, various operations described for RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8. In alternate embodiments, programming instructions 1004 may be disposed on multiple computer-readable storage media 1002. In alternate embodiments, storage medium 1002 may be transitory, e.g., signals encoded with programming instructions 1004.

Referring back to FIG. 9, for an embodiment, at least one of processors 902 may be packaged together with memory having computational logic 924 configured to practice aspects described for RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8. For an embodiment, at least one of processors 902 may be packaged together with memory having computational logic 924 configured to practice aspects described for RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8, to form a System in Package (SiP). For an embodiment, at least one of processors 902 may be integrated on the same die with memory having computational logic 924 configured to practice aspects described for RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8. For an embodiment, at least one of processors 902 may be packaged together with memory having computational logic 924 configured to practice aspects of RAE 100, RAE 202, RAE 302, RAE 402, RAE 708, RAE 716, RAE 726, RAE 740, RAE 744, or RAE 750 of FIGS. 1-5 and 7, or operations shown in process 800 of FIG. 8 to form a System on Chip (SoC). For at least one embodiment, the SoC may be utilized in, e.g., but not limited to, a mobile computing device such as a wearable device and/or a smartphone. In various embodiments, at least one of the processors 902 may be configured to cooperate with computational logic 924 to practice aspects of other components and/or modules of the RAE 909.

Machine-readable media (including non-transitory machine-readable media, such as machine-readable storage media), methods, systems and devices for performing the above-described techniques are illustrative examples of embodiments disclosed herein. Additionally, other devices in the above-described interactions may be configured to perform various disclosed techniques.

### Examples

Example 1 may include an apparatus with integral integrated circuit reliability assessment comprising: a reliability physics model stored in non-volatile memory; and compute logic to calculate at least one of an estimated amount of lifetime consumed or an estimated amount of lifetime remaining after a period of operation of the integrated circuit, wherein the calculation is based at least in part on the reliability physics model and data of at least one physical condition of the integrated circuit sensed during or at an end of the period of operation.

Example 2 may include the subject matter of Example 1, wherein the reliability physics model includes at least one of a time dependent dielectric breakdown model, a bias temperature stability model, an electromigration model, a negative/positive bias temperature model, an integrated reliability model, a package die crack model, an intrinsic charge loss model, a stress induced leakage current model, or a read/write disturb model.

Example 3 may include the subject matter of any one of Examples 1-2, wherein the data of at least one physical condition sensed during the period of operation includes one or more sensed voltages, average of the one or more sensed voltages, one or more sensed temperatures, average of the one or more sense temperatures, one or more workload measures, or average of the one or more workload measures.

Example 4 may include the subject matter of Example 3, wherein the reliability physics model is a first reliability physics model, the apparatus further includes a second reliability physics model and a statistical model to combine the first and second reliability physics models, and the compute logic is to calculate the estimated amount of lifetime remaining after the period of operation, based at least in part on the first reliability physics model, the second reliability physics model, and the statistical model.

Example 5 may include the subject matter of Example 4, wherein the statistical model is a Markov failure prediction model.

Example 6 may include the subject matter of any one of Examples 1-5, wherein the data of at least one physical condition sensed is received by the compute logic from a power control unit of the integrated circuit.

Example 7 may include the subject matter of any one of Examples 1-6, wherein the compute logic is also to adjust an operation parameter of the integrated circuit based at least in part on the calculated amount of integrated circuit lifetime remaining.

Example 8 may include the subject matter of any one of Examples 1-7, wherein the compute logic is also to compute: a first estimated amount of integrated circuit lifetime remaining after the period of operation, based at least in part on the reliability physics model, the data of at least one physical condition sensed, and a first proposed future operating condition of the integrated circuit; and a second estimated amount of integrated circuit lifetime remaining after the period of operation, based at least in part on the reliability physics model, the data of at least one physical condition sensed, and a second proposed future operating condition of the integrated circuit, wherein the first proposed future operating condition includes at least one of a first average voltage, a first average temperature, or a first average workload metric of the integrated circuit and the second proposed future operating condition includes at least one of a second average voltage, a second average temperature, or a second average workload metric of the integrated circuit.

Example 9 may include the subject matter of Example 8, wherein the compute logic is also to: receive an indication of a desired integrated circuit performance state corresponding to one of the first estimated amount of integrated circuit lifetime remaining and the second estimated amount of integrated circuit lifetime remaining; and adjust an operation parameter of the integrated circuit based at least in part on the received indication such that at least one of an average voltage, average temperature, or average workload metric of the integrated circuit remains within a predefined range of the first average voltage, first average temperature, or first average workload metric respectively in response to the indication corresponds to the first estimated amount of integrated circuit lifetime remaining, or the second average voltage, second average temperature, or second average workload metric respectively in response to the indication corresponds to the second estimated amount of integrated circuit lifetime remaining.

Example 10 may include an apparatus to assess reliability of an integrated circuit comprising: a plurality of reliability physics models stored in non-volatile memory; and compute logic to: receive an indication of an integrated circuit type in a self-identification procedure of an integrated circuit; receive data of at least one physical condition of the integrated circuit sensed during or at an end of a period of operation of the integrated circuit; select a reliability physics model from the plurality of reliability physics models based on the received indication; and calculate at least one of an estimated amount of lifetime consumed or an estimated amount of lifetime remaining after the period of operation for the integrated circuit, wherein the calculation is based at least in part on the selected reliability physics model and the received data.

Example 11 may include the subject matter of Example 10, wherein the plurality of reliability physics models includes at least two of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

Example 12 may include the subject matter of any one of Examples 10-11, wherein the data of at least one physical condition sensed during the period of operation includes one or more sensed voltages, average of the one or more sensed voltages, one or more sensed temperatures, average of the one or more sensed temperatures, one or more workload measures, or average of the one or more workload measures.

Example 13 may include the subject matter of any one of Examples 10-12, wherein the integrated circuit is a first integrated circuit, the indication is a first indication, and the compute logic is also to: receive a second indication of a second integrated circuit type in a self-identification procedure of a second integrated circuit; receive data of at least one physical condition of the second integrated circuit sensed during or at the end of a period of operation of the second integrated circuit; select a second reliability physics model from the plurality of reliability physics models based on the received second indication; and calculate at least one of an estimated amount of lifetime consumed or an estimated amount of lifetime remaining after the period of operation for the second integrated circuit, wherein the calculation is based at least in part on the selected second reliability physics model and the received data of the at least one physical condition of the second integrated circuit.

Example 14 may include the subject matter of Example 13, wherein the compute logic is also to generate a command to alter an operation parameter of at least one of the first integrated circuit and the second integrated circuit based at least in part on the calculated amount of lifetime remaining for the first integrated circuit and the calculated amount of lifetime remaining for the second integrated circuit.

Example 15 may include the subject matter of Example 14, wherein the compute logic is also to receive an indication of a desired integrated circuit performance state and adjust an operation parameter of at least one of the first integrated circuit the second integrated circuit based at least in part on the received indication.

Example 16 may include an apparatus to assess reliability of a non-volatile memory comprising: a raw bit error rate reliability physics model stored in non-volatile memory; and compute logic to calculate a raw bit error rate of a non-volatile memory cell block based at least in part on the raw bit error rate reliability physics model and data of at least one physical condition of the memory cell block sensed during or at the end of a period of operation of the memory cell block.

Example 17 may include the subject matter of Example 16, wherein the data of at least one physical condition sensed during the period of operation includes a read disturb measurement.

Example 18 may include the subject matter of Example 16, wherein the data of at least one physical condition sensed during the period of operation includes a number of program/erase cycles of the memory cell block and a read disturb measurement.

Example 19 may include the subject matter of any one of Examples 17-18, wherein the read disturb measurement includes at least one of a number of reads since the last erase of the memory cell block or a threshold program voltage shift measurement.

Example 20 may include the subject matter of any one of Examples 16-19, wherein the non-volatile memory cell block is part of a solid state drive and the compute logic is also to adjust a read-disturb handling rate of the non-volatile memory cell block based at least in part on the calculated raw bit error rate.

Example 21 may include a method for integrated circuit reliability assessment comprising: receiving, by a reliability assessment engine operating on an integrated circuit, data representing at least one physical condition of the integrated circuit sensed during or at the end of a period of operation of the integrated circuit; and calculating, by the reliability assessment engine, at least one of an estimated amount of lifetime consumed or an estimated amount of lifetime remaining after the period of operation of the integrated circuit, wherein the calculation is based at least in part on a reliability physics model and the received data.

Example 22 may include the subject matter of Example 21, wherein the reliability physics model includes at least one of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

Example 23 may include the subject matter of any one of Examples 21-22, wherein the data representing the at least one physical condition sensed during the period of operation includes at least two of one or more sensed voltages, average of the one or more sensed voltages, one or more sensed temperatures, average of the one or more sensed temperatures, one or more workload measures, or average of the one or more workload measures.

Example 24 may include the subject matter of any one of Examples 21-23, wherein the reliability physics model is a first reliability physics model, and calculating includes calculating the at least one of an estimated amount of lifetime consumed or the estimated amount of lifetime remaining based at least in part on the first reliability physics model, a second reliability physics model, and a statistical model to combine the first and second reliability physics models.

Example 25 may include the subject matter of Example 24, further comprising: receiving, by the reliability assessment engine, an indication of a desired integrated circuit performance state; and adjusting, by the reliability assessment engine, an operation parameter of the integrated circuit based at least in part on the received indication.

Example 26 may include one or more computer-readable media comprising instructions that cause a computing device, in response to execution of the instructions by the computing device, to: receive data representing at least one physical condition of an integrated circuit sensed during or at the end of a period of operation of the integrated circuit; and calculate at least one of an estimated amount of lifetime consumed or an estimated amount of lifetime remaining after the period of operation of the integrated circuit, wherein the calculation is based at least in part on a reliability physics model and the received data.

Example 27 may include the subject matter of Example 26, wherein the reliability physics model includes at least one of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

Example 28 may include the subject matter of any one of Examples 26-27, wherein the data representing the at least one physical condition sensed during the period of operation includes at least two of one or more sensed voltages, average of the one or more sensed voltages, one or more sensed temperatures, average of the one or more sensed temperatures, one or more workload measures, or average of the one or more workload measures.

Example 29 may include the subject matter of any one of Examples 26-28, wherein the reliability physics model is a first reliability physics model, and the instructions are to cause the computing device to calculate the at least one of an estimated amount of lifetime consumed or the estimated amount of lifetime remaining based at least in part on the first reliability physics model, a second reliability physics model, and a statistical model to combine the first and second reliability physics models.

Example 30 may include the subject matter of any one of Examples 26-29, wherein the instructions are to cause the computing device to receive an indication of a desired integrated circuit performance state and adjust an operation parameter of the integrated circuit based at least in part on the received indication.

Example 31 may include an apparatus to assess reliability of an integrated circuit comprising: means for receiving data representing at least one physical condition of the integrated circuit sensed during or at the end of a period of operation of the integrated circuit; and means for calculating at least one of an estimated amount of lifetime consumed or an estimated amount of lifetime remaining after the period of operation of the integrated circuit, wherein the calculation is based at least in part on a reliability physics model and the received data.

Example 32 may include the subject matter of Example 31, wherein the reliability physics model includes at least one of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

Example 33 may include the subject matter of any one of Examples 31-32, wherein the data representing the at least one physical condition sensed during the period of operation includes at least two of one or more sensed voltages, average of the one or more sensed voltages, one or more sensed temperatures, average of the one or more sensed temperatures, one or more workload measures, or average of the one or more workload measures.

Example 34 may include the subject matter of any one of Examples 33, wherein the reliability physics model is a first reliability physics model, and the means for calculating includes means for calculating the at least one of an estimated amount of lifetime consumed or the estimated amount of lifetime remaining based at least in part on the first reliability physics model, a second reliability physics model, and a statistical model to combine the first and second reliability physics models.

Example 35 may include the subject matter of any one of Examples 31-34, further comprising: means for receiving an indication of a desired integrated circuit performance state; and means for adjusting an operation parameter of the integrated circuit based at least in part on the received indication.

Example 36 may include the subject matter of any one of Examples 1-9, further comprising: one or more processors communicatively coupled to the compute logic and one or more of: a network interface communicatively coupled to the one or more processors, a display communicatively coupled to the one or more processors, or a battery coupled to the one or more processors.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements.

Further, ordinal indicators (e.g., first, second or third) for identified elements are used to distinguish between the elements, and do not indicate or imply a required or limited number of such elements, nor do they indicate a particular position or order of such elements unless otherwise specifically stated.

What is claimed is:

1. An apparatus with integral integrated circuit reliability assessment comprising:
a reliability physics model stored in non-volatile memory; and
compute logic to calculate at least one of an estimated amount of lifetime consumed or an estimated amount of lifetime remaining after a period of operation of the integrated circuit, wherein the calculation is based at least in part on the reliability physics model and data of at least one physical condition of the integrated circuit sensed during or at an end of the period of operation.

2. The apparatus of claim 1, wherein the reliability physics model includes at least one of a time dependent dielectric breakdown model, a bias temperature stability model, an electromigration model, a negative/positive bias temperature model, an integrated reliability model, a package die crack model, an intrinsic charge loss model, a stress induced leakage current model, or a read/write disturb model.

3. The apparatus of claim 1, wherein the data of at least one physical condition sensed during the period of operation includes one or more sensed voltages, average of the one or more sensed voltages, one or more sensed temperatures, average of the one or more sense temperatures, one or more workload measures, or average of the one or more workload measures.

4. The apparatus of claim 3, wherein the reliability physics model is a first reliability physics model, the apparatus further includes a second reliability physics model and a statistical model to combine the first and second reliability physics models, and the compute logic is to calculate the estimated amount of lifetime remaining after the period of operation, based at least in part on the first reliability physics model, the second reliability physics model, and the statistical model.

5. The apparatus of claim 4, wherein the statistical model comprises a Markov failure prediction model.

6. The apparatus of claim 1, wherein the data of at least one physical condition sensed is received by the compute logic from a power control unit of the integrated circuit.

7. The apparatus of claim 1, wherein the compute logic is also to adjust an operation parameter of the integrated circuit based at least in part on the calculated amount of integrated circuit lifetime remaining.

8. The apparatus of claim 1, wherein the compute logic is also to compute:
a first estimated amount of integrated circuit lifetime remaining after the period of operation, based at least in part on the reliability physics model, the data of at least one physical condition sensed, and a first proposed future operating condition of the integrated circuit; and
a second estimated amount of integrated circuit lifetime remaining after the period of operation, based at least in part on the reliability physics model, the data of at least one physical condition sensed, and a second proposed future operating condition of the integrated circuit,
wherein the first proposed future operating condition includes at least one of a first average voltage, a first average temperature, or a first average workload metric of the integrated circuit and the second proposed future operating condition includes at least one of a second average voltage, a second average temperature, or a second average workload metric of the integrated circuit.

9. The apparatus of claim 8, wherein the compute logic is also to:
receive an indication of a desired integrated circuit performance state corresponding to one of the first estimated amount of integrated circuit lifetime remaining and the second estimated amount of integrated circuit lifetime remaining; and
adjust an operation parameter of the integrated circuit based at least in part on the received indication such that at least one of an average voltage, average temperature, or average workload metric of the integrated circuit remains within a predefined range of the first average voltage, first average temperature, or first average workload metric respectively in response to the indication corresponds to the first estimated amount of integrated circuit lifetime remaining, or the second average voltage, second average temperature, or second average workload metric respectively in response to the indication corresponds to the second estimated amount of integrated circuit lifetime remaining.

10. The apparatus of claim 1 further comprising:
one or more processors communicatively coupled to the compute logic and one or more of:
a network interface communicatively coupled to the one or more processors,
a display communicatively coupled to the one or more processors, or
a battery coupled to the one or more processors.

11. An apparatus to assess reliability of an integrated circuit comprising:
a plurality of reliability physics models stored in non-volatile memory; and
compute logic to:
receive an indication of an integrated circuit type in a self-identification procedure of an integrated circuit;
receive data of at least one physical condition of the integrated circuit sensed during or at an end of a period of operation of the integrated circuit;
select a reliability physics model from the plurality of reliability physics models based on the received indication; and
calculate at least one of an estimated amount of lifetime consumed or an estimated amount of lifetime remaining after the period of operation for the integrated circuit, wherein the calculation is based at least in part on the selected reliability physics model and the received data.

12. The apparatus of claim 11, wherein the plurality of reliability physics models includes at least two of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

13. The apparatus of claim 11, wherein the data of at least one physical condition sensed during the period of operation includes one or more sensed voltages, average of the one or more sensed voltages, one or more sensed temperatures, average of the one or more sensed temperatures, one or more workload measures, or average of the one or more workload measures.

14. The apparatus of claim 11, wherein the integrated circuit comprises a first integrated circuit, the indication is a first indication, and the compute logic is also to:
receive a second indication of a second integrated circuit type in a self-identification procedure of a second integrated circuit;
receive data of at least one physical condition of the second integrated circuit sensed during or at the end of a period of operation of the second integrated circuit;
select a second reliability physics model from the plurality of reliability physics models based on the received second indication; and
calculate at least one of an estimated amount of lifetime consumed or an estimated amount of lifetime remaining after the period of operation for the second integrated circuit, wherein the calculation is based at least in part on the selected second reliability physics model and the received data of the at least one physical condition of the second integrated circuit.

15. The apparatus of claim 14, wherein the compute logic is also to generate a command to alter an operation parameter of at least one of the first integrated circuit and the second integrated circuit based at least in part on the calculated amount of lifetime remaining for the first integrated circuit and the calculated amount of lifetime remaining for the second integrated circuit.

16. The apparatus of claim 15, wherein the compute logic is also to receive an indication of a desired integrated circuit performance state and adjust an operation parameter of at least one of the first integrated circuit the second integrated circuit based at least in part on the received indication.

17. An apparatus to assess reliability of a non-volatile memory comprising:
a raw bit error rate reliability physics model stored in non-volatile memory; and
compute logic to calculate a raw bit error rate of a non-volatile memory cell block based at least in part on the raw bit error rate reliability physics model and data of at least one physical condition of the memory cell block sensed during or at the end of a period of operation of the memory cell block.

18. The apparatus of claim 17, wherein the data of at least one physical condition sensed during the period of operation includes a read disturb measurement.

19. The apparatus of claim 17, wherein the data of at least one physical condition sensed during the period of operation includes a number of program/erase cycles of the memory cell block and a read disturb measurement.

20. The apparatus of claim 19, wherein the read disturb measurement includes at least one of a number of reads since the last erase of the memory cell block or a threshold program voltage shift measurement.

21. The apparatus of claim 17, wherein the non-volatile memory cell block is part of a solid state drive and the compute logic is also to adjust a read-disturb handling rate of the non-volatile memory cell block based at least in part on the calculated raw bit error rate.

22. One or more computer-readable media comprising instructions that cause a computing device, in response to execution of the instructions by the computing device, to:
receive data representing at least one physical condition of an integrated circuit sensed during or at the end of a period of operation of the integrated circuit; and
calculate at least one of an estimated amount of lifetime consumed or an estimated amount of lifetime remaining after the period of operation of the integrated circuit, wherein the calculation is based at least in part on a reliability physics model and the received data.

23. The computer-readable media of claim 22, wherein the reliability physics model includes at least one of a time dependent dielectric breakdown model, a bias temperature stability model, an electromigration model, a negative/positive bias temperature instability model, an integrated reliability model, a package die crack model, an intrinsic charge loss model, a stress induced leakage current model, or a read/write disturb model.

24. The computer-readable media of claim 22, wherein the data representing the at least one physical condition sensed during the period of operation includes at least two of one or more sensed voltages, average of the one or more sensed voltages, one or more sensed temperatures, average of the one or more sensed temperatures, one or more workload measures, or average of the one or more workload measures.

25. The computer-readable media of claim 24, wherein the reliability physics model is a first reliability physics model, and the instructions are to cause the computing device to calculate the at least one of an estimated amount of lifetime consumed or the estimated amount of lifetime remaining based at least in part on the first reliability physics model, a second reliability physics model, and a statistical model to combine the first and second reliability physics models.

26. The computer readable media of claim 25, wherein the instructions are to cause the computing device to receive an indication of a desired integrated circuit performance state and adjust an operation parameter of the integrated circuit based at least in part on the received indication.
